(19) United States
(12) Patent Application Publication
(10) Pub. No.: US 2026/0279736 A1
(43) Pub. Date: Sep. 17, 2026

(54) A PLASMA ETCH-RESISTANT FILM AND A METHOD FOR ITS FABRICATION

(71) Applicant: Beneq Oy, Espoo (FI)

(72) Inventors: Lassi Leppilahti, Espoo (FI); Mikko Saikkonen, Espoo (FI)

(21) Appl. No.: 19/480,130

(22) PCT Filed: Apr. 25, 2024
(86) PCT No.: PCT/FI2024/050193

§ 371 Date: Oct. 30, 2025

(30) Foreign Application Priority Data
May 2, 2023 (FI) 20235484

(51) Int. Cl. H01J 37/32; C23C 16/40; C23C 16/455

(52) U.S. Cl. CPC H01J 37/32495; C23C 16/405; C23C 16/45529; H01J 2237/334

(57) ABSTRACT

A method for fabricating a plasma etch-resistant film on a surface of a substrate is disclosed. The method comprises the steps of forming, in a reaction space by exposing a deposition surface to alternately repeated, essentially self-limiting surface reactions of precursors, one precursor at a time, —an intermediate layer of dielectric material on the surface of the substrate, and—a protective layer on the intermediate layer, to form a plasma etch-resistant film for hindering current passing through the plasma-etch resistant film to the substrate. Further is disclosed a plasma etch-resistant film and uses thereof.

### FIELD OF THE INVENTION

The present disclosure relates to a method for fabricating a plasma etch-resistant film on a surface of a substrate. The present disclosure relates further to a plasma etch-resistant film on a surface of a substrate. The present disclosure relates further to the use of the plasma etch-resistant film.

### BACKGROUND OF THE INVENTION

The surfaces and components of a plasma reaction chamber are subjected to harsh conditions during the employed process. The resistance to plasmas is thus a desirable property for components used in processing chambers where corrosive environments are present. Therefore, protecting components against such corrosive environment is desired in order to prolong the lifetime of the used components or chambers. To reduce the erosion or degradation of the surfaces exposed to the corrosive environment, thick coatings or films of e.g. aluminum oxide have been formed on the surfaces that are to be protected. The aim of such coatings or films is to act to reduce exposure of the surface to be protected to various plasmas based on e.g. NF₃, CF₄, CHF₃, CH₂F₂, C₂F₆, SF₆, Cl₂ and HBr. However, although these coatings or films exhibit improved plasma resistance, they often have porous structure as a result of e.g. the used fabrication method. Thus, with time, the porous structure allows the adverse effects of the corrosive environment to penetrate through the coating to the surface to be protected and/or to form solid particles that contaminate the surroundings. Also, thick films may easily crack whereby its protective effect is easily lost. Using e.g. plasma spraying to form the coating does also not provide a conformal coating.

Thus, there remains a need for a method enabling to fabricate a long-lasting plasma etch-resistant film with properties suitable for protecting e.g. the surfaces of a plasma chamber and components thereof against the detrimental processing conditions.

### SUMMARY

A method for fabricating a plasma etch-resistant film on a surface of a substrate is disclosed. The method comprises the steps of forming, in a reaction space by exposing a deposition surface to alternately repeated, essentially self-limiting surface reactions of precursors, one precursor at a time,
an intermediate layer of dielectric material on the surface of the substrate, wherein the dielectric material is a nanolaminate of two or more different metal oxides, and wherein the thickness of the intermediate layer is 100-500 nm, and
a protective layer on the intermediate layer, wherein the material of the protective layer is selected from a group consisting of a rare earth metal oxide, a rare earth metal fluoride, a rare earth metal oxyfluoride, and any combination or mixture thereof, and wherein the thickness of the protective layer is 100-3000 nm,
to form a plasma etch-resistant film for hindering current passing through the plasma-etch resistant film to the substrate.

Further is disclosed a plasma etch-resistant film on a surface of a substrate. The plasma etch-resistant film comprises: —an intermediate layer of dielectric material on the surface of the substrate, wherein the dielectric material is a nanolaminate of two or more different metal oxides, and wherein the thickness of the intermediate layer is 100-500 nm; and—a protective layer on the intermediate layer, wherein the material of the protective layer is selected from a group consisting of a rare earth metal oxide, a rare earth metal fluoride, a rare earth metal oxyfluoride, and any combination or mixture thereof. The thickness of the protective layer is 100-3000 nm. The plasma etch-resistant film hinders current passing through the plasma-etch resistant film to the substrate.

Further is disclosed the use of the plasma etch-resistant film as disclosed in the current specification for protecting a surface of a plasma chamber against the detrimental effects of the processing conditions used in the plasma chamber.

Further is disclosed the use of the plasma etch-resistant film as disclosed in the current specification for inhibiting or hindering current used in a plasma chamber from passing through the plasma etch-resistant film to the substrate under the voltage experienced in a plasma process.

### BRIEF DESCRIPTION OF THE DRAWINGS

The accompanying drawings, which are included to provide a further understanding of the method and the substrate and constitute a part of this specification, illustrate embodiments and together with the description help to explain the principles of the above. In the drawings:

FIG. 1 is a schematic illustration of a plasma etch-resistant film on a substrate according to one embodiment.

### DETAILED DESCRIPTION

A method for fabricating a plasma etch-resistant film on a surface of a substrate is disclosed. The method comprises the steps of forming, in a reaction space by exposing a deposition surface to alternately repeated, essentially self-limiting surface reactions of precursors, one precursor at a time,
an intermediate layer of dielectric material on the surface of the substrate, wherein the dielectric material is a nanolaminate of two or more different metal oxides, and wherein the thickness of the intermediate layer is 100-500 nm, and
a protective layer on the intermediate layer, wherein the material of the protective layer is selected from a group consisting of a rare earth metal oxide, a rare earth metal fluoride, a rare earth metal oxyfluoride, and any combination or mixture thereof, and wherein the thickness of the protective layer is 100-3000 nm,
to form a plasma etch-resistant film for hindering current passing through the plasma-etch resistant film to the substrate.

A method for fabricating a plasma etch-resistant film on a surface of a substrate is disclosed.

The method comprises the steps of forming, in a reaction space by exposing a deposition surface to alternately repeated, essentially self-limiting surface reactions of precursors, one precursor at a time,
an intermediate layer of dielectric material on the surface of the substrate, wherein the dielectric material is a nanolaminate of two or more different metal oxides, and wherein the thickness of the intermediate layer is 100-500 nm, and
a protective layer on the intermediate layer, wherein the material of the protective layer is selected from a group consisting of a rare earth metal oxide, a rare earth metal fluoride, a rare earth metal oxyfluoride, aluminum oxide, and any combination or mixture thereof, and wherein the thickness of the protective layer is 100-3000 nm,
to form a plasma etch-resistant film for hindering current passing through the plasma-etch resistant film to the substrate.

The term “current” should be understood to refer to electric current.

In this specification, unless otherwise stated, the term “the surface”, “surface of the substrate”, or “deposition surface”, is used to address the surface of the substrate or the surface of the already formed layer or deposit on the substrate. Therefore, the terms “surface”, “surface of the substrate”, and “deposition surface” include the surface of the substrate which has not yet been exposed to any precursors and the surface which has been exposed to one or more precursors. The “deposition surface” thus changes during the deposition process when chemicals get chemisorbed onto the surface.

Further is disclosed a plasma etch-resistant film on a surface of a substrate. The plasma etch-resistant film comprises: —an intermediate layer of dielectric material on the surface of the substrate, wherein the dielectric material is a nanolaminate of two or more different metal oxides, and wherein the thickness of the intermediate layer is 100-500 nm; and—a protective layer on the intermediate layer, wherein the material of the protective layer is selected from a group consisting of a rare earth metal oxide, a rare earth metal fluoride, a rare earth metal oxyfluoride, and any combination or mixture thereof, and wherein the thickness of the protective layer is 100-3000 nm. The plasma etch-resistant film hinders current passing through the plasma-etch resistant film to the substrate.

Further is disclosed a plasma etch-resistant film on a surface of a substrate. The plasma etch-resistant film comprises: —an intermediate layer of dielectric material on the surface of the substrate, wherein the dielectric material is a nanolaminate of two or more different metal oxides, and wherein the thickness of the intermediate layer is 100-500 nm; and—a protective layer on the intermediate layer, wherein the material of the protective layer is selected from a group consisting of a rare earth metal oxide, a rare earth metal fluoride, a rare earth metal oxyfluoride, aluminum oxide, and any combination or mixture thereof, and wherein the thickness of the protective layer is 100-3000 nm. The plasma etch-resistant film hinders current passing through the plasma-etch resistant film to the substrate.

Further is disclosed the use of the plasma etch-resistant film as disclosed in the current specification for protecting a surface of a plasma chamber against the detrimental effects of the processing conditions used in the plasma chamber.

Further is disclosed the use of the plasma etch-resistant film as disclosed in the current specification for hindering or inhibiting current used in a plasma chamber from passing through the plasma etch-resistant film to the substrate.

Electrical breakdown or dielectric breakdown is a process that occurs when an electrical insulating material, subjected to a high enough voltage, suddenly becomes an electrical conductor and electric current flows through it. All insulating materials undergo breakdown when the electric field caused by an applied voltage exceeds the dielectric strength of the material. The voltage at which a given insulating object becomes conductive is called its breakdown voltage and in addition to its dielectric strength depends on its size and shape, and the location on the object at which the voltage is applied.

The inventors surprisingly found out that it is possible to fabricate a plasma etch-resistant film comprising a protective layer having high performance in terms of plasma resistance while an intermediate layer of dielectric material between a substrate and the protective layer assists in providing a high breakdown voltage structure to the plasma etch-resistant film without having to fabricate a thick film or without having to prepare the distinct films in different reaction chambers.

The method may comprise forming a plasma etch-resistant film having a breakdown voltage value of at least 200 V, or at least 230 V, or at least 250 V, or at least 270 V, or at least 300 V, when measured for the plasma etch-resistant film as described in the description at a total film thickness of 700 nm. The plasma etch-resistant film may have a breakdown voltage value of at least 200 V, or at least 230 V, or at least 250 V, or at least 270 V, or at least 300 V, when measured for the plasma etch-resistant film as described in the description at a film thickness of 700 nm. The breakdown voltage value may be affected by the thickness of the plasma etch-resistant film. The thicker the plasma etch-resistant film is, the higher may the breakdown voltage value be. However, the plasma etch-resistant film as disclosed in the current specification has the added utility of providing a high breakdown voltage value while simultaneously being rather thin in total thickness.

The breakdown voltage value may be measured by using the produced plasma etch-resistant film on a surface of a substrate and by increasing the voltage subjected thereto until the dielectric breakdown there through is reached. As the breakdown voltage value of the material of the substrate is known, one may calculate the corresponding value of the plasma etch-resistant film. Thus, the breakdown voltage value may be measured by conducting IV (current-voltage) measurements on film samples of the size of 4 cm×4 cm and a total thickness of 700 nm using an IV Plotter with a Mercury Probe with a front-back configuration. Voltage is swept from 0 V to 1000 V in 10 V steps. Breakdown voltage is determined at a current of 1 μA.

The dielectric material is a nanolaminate of two or more different metal oxides. In one embodiment, the dielectric material is an aluminum titanium oxide (ATO) nanolaminate.

In one embodiment, the nanolaminate of two or more different metal oxides is a nanolaminate of aluminum oxide and a rare earth metal oxide. In one embodiment the nanolaminate of two or more different metal oxides is a nanolaminate of aluminum oxide and yttrium oxide.

The inventors surprisingly found out that using a nanolaminate of two or more different metal oxides as the intermediate layer has the added utility of providing good adhesion to the substrate while efficiently hindering current from passing from the surrounding through the plasma etch-resistant film to the substrate.

In this specification, unless otherwise stated, the term “nanolaminate” is used to address distinct layers of different metal oxide material one upon the other. The distinct layers of different material may not be diffused or mixed into each other. The thickness of the distinct layers in the nanolaminate may be of nanoscale, such as 0.5-20 nm. The distinct layers of material may thus have the thickness of a monolayer. The nanolaminate may comprise at least 6, or at least 8, or at least 10, or at least 15, layers of each of the different metal oxides. The nanolaminate may comprise 6-500, or 8-400, or 10-300, or 15-200, or 20-100, or 25-50, or 30-40, layers of each of the different metal oxides.

In one embodiment, the material of the protective layer is aluminum oxide.

In one embodiment, the material of the protective layer is selected from a group consisting of a rare earth metal oxide, a rare earth metal fluoride, a rare earth metal oxyfluoride, and any combination or mixture thereof. Thus, the material of the protective layer may be a rare earth metal oxide, a rare earth metal fluoride, a rare earth metal oxyfluoride, or any combination or mixture thereof. The material of the protective layer may thus be of a combination of a rare earth metal oxide, a rare earth metal fluoride, and/or a rare earth metal oxyfluoride. In one embodiment, the material of the protective layer is a rare earth metal oxide. The rare earth metal based protective layer has the added utility of providing a high protection of the substrate to the harsh conditions used in a plasma chamber.

The rare earth metal may be selected from scandium, yttrium, lanthanum, cerium, praseodymium, neodymium, samarium, europium, gadolinium, terbium, dysprosium, holmium, erbium, thulium, ytterbium, and lutetium. In one embodiment, the rare-earth metal is yttrium.

According to the International Union of Pure and Applied Chemistry (IUPAC) the lanthanides as well as yttrium and scandium are considered rare-earth metals.

The rare earth metal oxide may be yttrium oxide, cerium oxide, dysprosium oxide, erbium oxide, or gadolinium oxide. In one embodiment, the rare earth metal oxide is yttrium oxide.

The rare earth metal fluoride may be yttrium fluoride, cerium fluoride, dysprosium fluoride, erbium fluoride, or gadolinium fluoride. In one embodiment, the rare earth metal fluoride is yttrium fluoride.

The rare earth metal oxyfluoride may be yttrium oxyfluoride, cerium oxyfluoride, dysprosium oxyfluoride, erbium oxyfluoride, or gadolinium oxyfluoride. In one embodiment, the rare earth metal oxyfluoride is yttrium oxyfluoride.

Different precursors to be used in the method described in the current specification for producing the materials of the intermediate layer and the protective layer are generally available and will be obvious to the skilled person.

The substrate may be formed of ceramic, metal, and/or glass. In one embodiment, the substrate is formed of metal. The metal may be porous metal. The glass may be porous glass.

The method may comprise forming a plasma etch-resistant film having a total thickness of 200-3500 nm, or 150-6000 nm, or 300-5500 nm, or 450-2300 nm, or 650-1100 nm. The plasma etch-resistant film may have a thickness of 200-3500 nm, or 150-6000 nm, or 300-5500 nm, or 450-2300 nm, or 650-1100 nm. Being able to form a rather thin plasma etch-resistant film while simultaneously having a high breakdown voltage value has the added utility of less starting material, i.e. precursor chemicals, being needed for the fabrication process, as well as reducing the production cost and time. Being able to form a rather thin plasma etch-resistant film has the further added utility of providing good adhesion to the surface of the substrate.

The method may comprise forming an intermediate layer having a thickness of 100-500 nm, or 130-450 nm, or 150-400 nm, or 200-300 nm. The intermediate layer may have a thickness of 100-500 nm, or 130-450 nm, or 150-400 nm, or 200-300 nm.

The method may comprise forming a protective layer having a thickness of 100-2000 nm, or 200-1500 nm, or 300-1000 nm, or 400-900 nm, or 500-800 nm. The protective layer may have a thickness of 100-2000 nm, or 200-1500 nm, or 300-1000 nm, or 400-900 nm, or 500-800 nm.

The plasma etch-resistant film may be fabricated on the surface of the substrate in a reaction space with an atomic layer deposition type process. When the intermediate layer and the protective layer are fabricated on the surface of the substrate by an ALD-type process excellent conformality and uniformity is achieved for the formed layer(s).

The ALD-type process is a method for depositing uniform and conformal deposits or layers over substrates of various shapes, even over complex three-dimensional structures. In the ALD-type process, the substrate is alternately exposed to at least two different precursors (chemicals), usually one precursor at a time, to form on the substrate a deposit or a layer by alternately repeating essentially self-limiting surface reactions between the surface of the substrate (on the later stages, naturally, the surface of the already formed layer or deposit on the substrate) and the precursors. As a result, the deposited material is “grown” on the substrate molecule layer by molecule layer.

The distinctive feature of the ALD-type process is that the surface to be deposited is exposed to two or more different precursors in an alternate manner with usually a purging period in between the precursor pulses. During a purging period the deposition surface is exposed to a flow of gas which does not react with the precursors used in the process. This gas, often called the carrier gas or the purge gas, is therefore inert towards the precursors used in the process and removes e.g. surplus precursor and by-products resulting from the chemisorption reactions of the previous precursor pulse. This purging can be arranged by different means. The basic requirement of the ALD-type process is that the deposition surface is purged between the introduction of a precursor for a metal and a precursor for a non-metal. The purging period ensures that the gas phase growth is limited and only surfaces exposed to the precursor gas participate in the growth. However, the purging step with an inert gas can, according to one embodiment, be omitted in the ALD-type process when applying two process gases, i.e. different precursors, which do not react with each other. It can be mentioned, as an example only, that the purging period can be omitted between two precursors, which do not react with each other. I.e. the purging period can be omitted, in some embodiments, e.g. between two different precursors for oxygen if they do not react with each other.

The alternate or sequential exposure of the deposition surface to different precursors can be carried out in different manners. In a batch type process at least one substrate is placed in a reaction space, into which precursor and purge gases are being introduced in a predetermined cycle. Spatial atomic layer deposition is an ALD-type process based on the spatial separation of precursor gases or vapors. The different precursor gases or vapors can be confined in specific process areas or zones while the substrate passes by. In the continuous ALD-type process constant gas flow zones separated in space and a moving substrate are used in order to obtain the time sequential exposure. By moving the substrate through stationary zones, providing precursor exposure and purging areas, in the reaction space, a continuous coating process is achieved enabling roll-to-roll coating of a substrate. In continuous ALD-type process the cycle time depends on the speed of movement of the substrate between the gas flow zones.

Other names besides atomic layer deposition (ALD) have also been employed for these types processes, where the alternate introduction of or exposure to two or more different precursors lead to the growth of the layer, often through essentially self-limiting surface reactions. These other names or process variants include atomic layer epitaxy (ALE), atomic layer chemical vapour deposition (ALCVD), and corresponding plasma enhanced, photo-assisted and electron enhanced variants. Unless otherwise stated, also these processes will be collectively addressed as ALD-type processes in this specification.

The method as disclosed in the current specification has the added utility of providing a plasma etch-resistant film having a high breakdown voltage value inhibiting current passing through the plasma-etch resistant film to the substrate.

The method as disclosed in the current specification has the added utility of one being able to produce a plasma etch-resistant film with a high breakdown voltage value while keeping the film thickness thin.

The method as disclosed in the current specification has the added utility of providing a manner to produce a plasma etch-resistant film in an economical manner.

### EXAMPLES

Reference will now be made in detail to the described embodiments, examples of which are illustrated in the accompanying drawings.

The description below discloses some embodiments in such a detail that a person skilled in the art is able to utilize the method based on the disclosure. Not all steps of the embodiments are discussed in detail, as many of the steps will be obvious for the person skilled in the art based on this specification.

For reasons of simplicity, item numbers will be maintained in the following exemplary embodiments in the case of repeating components.

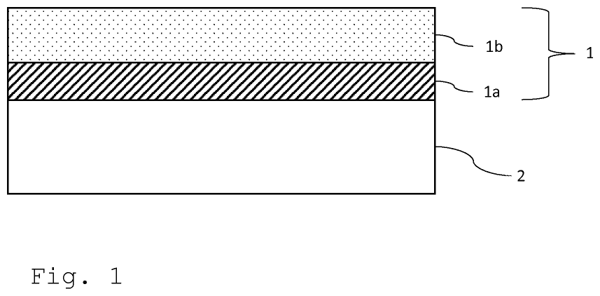

FIG. 1 illustrates a plasma etch-resistant film on the surface of the substrate according to one embodiment.

As presented above the ALD-type process is a method for depositing uniform and conformal films or layers over substrates of various shapes. Further, as presented above in ALD-type processes the layer or film is grown by alternately repeating, essentially self-limiting, surface reactions between a precursor and a surface to be coated. The prior art discloses many different apparatuses suitable for carrying out an ALD-type process. The construction of a processing tool suitable for carrying out the methods in the following embodiments will be obvious to the skilled person in light of this disclosure. The tool can be e.g. a conventional ALD tool suitable for handling the process chemicals. Many of the steps related to handling such tools, such as delivering a substrate into the reaction space, pumping the reaction space down to a low pressure, or adjusting gas flows in the tool if the process is done at atmospheric pressure, heating the substrates and the reaction space etc., will be obvious to the skilled person. Also, many other known operations or features are not described here in detail nor mentioned, in order to emphasize relevant aspects of the various embodiments of the invention.

FIG. 1 illustrate a plasma etch-resistant film 1 on the surface of a substrate 2 according to one embodiment. This exemplary embodiment may be fabricated by bringing the substrate 2 into a reaction space of a typical reactor tool, e.g. a tool suitable for carrying out an ALD-type process as a batch-type process. The reaction space is subsequently pumped down to a pressure suitable for forming a plasma etch-resistant film 1, using e.g. a mechanical vacuum pump, or in the case of atmospheric pressure ALD systems and/or processes, flows are typically set to protect the deposition zone from the atmosphere. The substrate 2 is also heated to a temperature suitable for forming the film 1 by the used method. The substrate 2 can be introduced to the reaction space through e.g. an airtight load-lock system or simply through a loading hatch. The substrate 2 can be heated in situ by e.g. resistive heating elements which also heat the entire reaction space or ex situ.

After the substrate 2 and the reaction space have reached the targeted temperature and other conditions suitable for deposition, the surface of the substrate can be conditioned such that the different layers 1a, 1b may be essentially directly deposited on the surface. This conditioning of the surface commonly includes chemical purification of the surface of the substrate 2 from impurities and/or oxidation. Especially removal of oxide is beneficial when the surface has been imported into the reaction space via an oxidizing environment, e.g. when transporting the exposed substrate from one deposition tool to another. The details of the process for removing impurities and/or oxide from the surface of the substrate will be obvious to the skilled person in view of this specification. In some embodiments of the invention the conditioning can be done ex-situ, i.e. outside the tool suitable for ALD-type processes. An example of an ex-situ conditioning process is etching for 1 min in a 1% HF solution followed by rinsing in DI-water. Another example of an ex-situ conditioning process is exposing the substrate to ozone gas or oxygen plasma to remove organic impurities from the substrate surface in the form of volatile gases.

After the surface of the substrate 2 has been conditioned, an alternate exposure of the deposition surface to different chemicals is started, to form a plasma etch-resistant film 1 directly on the surface of the substrate 2.

The precursors are suitably introduced into the reaction space in their gaseous form. This can be realized by first evaporating the precursors in their respective source containers which may or may not be heated depending on the properties of the precursor chemical itself. The evaporated precursor can be delivered into the reaction space by e.g. dosing it through the pipework of the reactor tool comprising flow channels for delivering the vaporized precursors into the reaction space. Controlled dosing of vapor into the reaction space can be realized by valves installed in the flow channels or other flow controllers. These valves are commonly called pulsing valves in a system suitable for ALD-type deposition.

Also other mechanisms of bringing the substrate 2 into contact with a chemical inside the reaction space may be conceived. One alternative is to make the surface of the substrate (instead of the vaporized chemical) move inside the reaction space such that the substrate moves through a region occupied by a gaseous chemical.

A reactor suitable for ALD-type deposition comprises a system for introducing carrier gas, such as nitrogen or argon into the reaction space such that the reaction space can be purged from surplus chemical and reaction by-products before introducing the next chemical into the reaction space. This feature together with the controlled dosing of vaporized precursors enables alternately exposing the surface of the substrate to precursors without significant intermixing of different precursors in the reaction space or in other parts of the reactor. In practice the flow of carrier gas is commonly continuous through the reaction space throughout the deposition process and only the various precursors are alternately introduced to the reaction space with the carrier gas. Obviously, purging of the reaction space does not necessarily result in complete elimination of surplus precursors or reaction by-products from the reaction space but residues of these or other materials may always be present.

Following the step of various preparations, the intermediate layer of dielectric material 1a, wherein the dielectric material is a nanolaminate of two or more different metal oxides, is deposited on the deposition surface by exposing the deposition surface to alternately repeated surface reactions of selected precursors, one precursor at a time, until a predetermined thickness of the intermediate layer is achieved. Then a protective layer 1b of a rare earth metal oxide, a rare earth metal fluoride, a rare earth metal oxyfluoride, aluminum oxide, or of any combination or mixture thereof is formed on the intermediate layer 1a until a predetermined thickness of the protective layer 1b is reached.

Each exposure of the deposition surface to a precursor results in formation of additional deposit on the deposition surface as a result of adsorption reactions of the corresponding precursor with the deposition surface. Thickness of the plasma etch-resistant film 1 on the surface of the substrate 2 can be increased by repeating the exposure to the different precursors one or more times. The thickness of the film is increased until a targeted thickness is reached, after which the alternate exposures are stopped and the process is ended. As a result of the deposition process a plasma etch-resistant film 1 is formed on the surface of the substrate 2 having an intermediate layer 1a and a protective layer 1b. The plasma etch-resistant film 1 also has excellent thickness uniformity and compositional uniformity along the deposition surface.

The following example describes how a plasma etch resistant film can be fabricated on a surface of a substrate.

### Example 1—Forming a Plasma Etch-Resistant Film on a Substrate

In this example a plasma etch-resistant film on a surface of a substrate was prepared in the above described manner. Also a comparative example was formed. The breakdown voltage values of the prepared samples were measured as described above in the description.

In the below table is presented the films formed as well as the test results:

TABLE 1

| | |
|---|---|
| | Comparative |
| Example 1 | example 1 |

| | | |
|---|---|---|
| Substrate | Si | Si |
| Intermediate layer | Nanolaminate of | — |
| | Al₂O₃ + Y₂O₃ * | |
| Precursors used | (MeCp)₃Y, | — |
| for forming the | TMA and H₂O | |
| intermediate layer | | |

| | | | |
|---|---|---|---|
| Thickness of the | 200 | nm | — |
| intermediate layer | | | |

| | | |
|---|---|---|
| Protective layer | Y₂O₃ | Y₂O₃ |
| Precursors used | (MeCp)₃Y | (MeCp)₃Y |
| for forming the | and H₂O | and H₂O |
| protective layer | | |

| | | | | |
|---|---|---|---|---|
| Thickness of the | 500 | nm | 500 | nm |
| protective layer | | | | |
| Temperature of the | 300° | C. | 300° | C. |
| reaction space | | | | |
| Measured breakdown | 233 | V | 40 | V |
| voltage value | | | | |

TMA = trimethylaluminium
(MeCp)₃Y = Tris(methylcyclopentadienyl)yttrium
* Nanolaminate = 20 × (5 nm Y₂O₃ + 5 nm Al₂O₃)

From the results in Table 1 one can see that the plasma etch-resistant film of example 1 exhibits a higher measured breakdown voltage value than the film of the comparative example 1.

It is obvious to a person skilled in the art that with the advancement of technology, the basic idea may be implemented in various ways. The embodiments are thus not limited to the examples described above; instead they may vary within the scope of the claims.

The embodiments described hereinbefore may be used in any combination with each other. Several of the embodiments may be combined together to form a further embodiment. A method, a plasma etch-resistant film, or a use as disclosed herein, may comprise at least one of the embodiments described hereinbefore. It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item refers to one or more of those items. The term “comprising” is used in this specification to mean including the feature(s) or act(s) followed thereafter, without excluding the presence of one or more additional features or acts.

1. A method for fabricating a plasma etch-resistant film on a surface of a substrate, wherein the method comprises the steps of forming, in a reaction space by exposing a deposition surface to alternately repeated, essentially self-limiting surface reactions of precursors, one precursor at a time,
an intermediate layer of dielectric material on the surface of the substrate, wherein the dielectric material is a nanolaminate of two or more different metal oxides, and wherein the thickness of the intermediate layer is 100-500 nm, and
a protective layer on the intermediate layer, wherein the material of the protective layer is selected from a group consisting of a rare earth metal oxide, a rare earth metal fluoride, a rare earth metal oxyfluoride, and any combination or mixture thereof, and wherein the thickness of the protective layer is 100-3000 nm,
to form a plasma etch-resistant film for hindering current passing through the plasma-etch resistant film to the substrate.

2. The method of claim 1, wherein the method comprises forming a plasma etch-resistant film having a breakdown voltage value of at least 200 V when measured for the plasma etch-resistant film as described in the description at a total film thickness of 700 nm.

3. The method of claim 1, wherein the dielectric material is an aluminum titanium oxide (ATO) nanolaminate.

4. The method of claim 1, wherein the nanolaminate of two or more different metal oxides is a nanolaminate of aluminum oxide and a rare earth metal oxide.

5. The method of claim 1, wherein the rare earth metal is selected from scandium, yttrium, lanthanum, cerium, praseodymium, neodymium, samarium, europium, gadolinium, terbium, dysprosium, holmium, erbium, thulium, ytterbium, and lutetium.

6. The method of claim 1, wherein the substrate is formed of ceramic, metal, and/or glass.

7. The method of claim 1, wherein the method comprises forming a plasma etch-resistant film having a total thickness of 200-3500 nm.

8. The method of claim 1, wherein the method comprises forming an intermediate layer having a thickness of 100-500 nm.

9. The method of claim 1, wherein the method comprises forming a protective layer having a thickness of 100-2000 nm.

10. The method of claim 1, wherein the plasma etch-resistant film is fabricated on the surface of the substrate in a reaction space with an atomic layer deposition type process.

11. A plasma etch-resistant film on a surface of a substrate, wherein the plasma etch-resistant film comprises:
an intermediate layer of dielectric material on the surface of the substrate, wherein the dielectric material is a nanolaminate of two or more different metal oxides, the intermediate layer having a thickness of 100-500 nm, and
a protective layer on the intermediate layer, wherein the protective layer comprises a material selected from a group consisting of a rare earth metal oxide, a rare earth metal fluoride, a rare earth metal oxyfluoride, and any combination or mixture thereof, the protective layer having a thickness of 100-3000 nm, and
wherein the plasma etch-resistant film hinders current passing through the plasma-etch resistant film to the substrate.

12. The plasma etch-resistant film of claim 11, wherein the plasma etch-resistant film has a breakdown voltage value of least 200 V when measured for the plasma etch-resistant film at a total film thickness of 700 nm.

13. The plasma etch-resistant film of claim 11, wherein the dielectric material is an aluminum titanium oxide (ATO) nanolaminate.

14. The plasma etch-resistant film of claim 11, wherein the nanolaminate of two or more different metal oxides is a nanolaminate of aluminum oxide and a rare earth metal oxide.

15. The plasma etch-resistant film of claim 11, wherein the rare earth metal is selected from scandium, yttrium, lanthanum, cerium, praseodymium, neodymium, samarium, europium, gadolinium, terbium, dysprosium, holmium, erbium, thulium, ytterbium, and lutetium.

16. The plasma etch-resistant film of claim 11, wherein the substrate is formed of ceramic, metal, and/or glass.

17. The plasma etch-resistant film of claim 11, wherein the plasma etch-resistant film has a total thickness of 200-3500 nm.

18. The plasma etch-resistant film of claim 11, wherein the intermediate layer has a thickness of 100-500 nm.

19. The plasma etch-resistant film of claim 11, wherein the protective layer has a thickness of 100-2000 nm.

20. A method of the plasma etch-resistant film of claim 11, the method comprising:
applying the plasma etch-resistant film to the plasma chamber and applying processing conditions used in the plasma chamber, thereby protecting a surface of the plasma chamber against detrimental effects of the processing conditions.

21. A method of using the plasma etch-resistant film of claim 11, the method comprising:
applying the plasma etch-resistant film to the plasma chamber and applying a voltage of a plasma process, thereby inhibiting or hindering a current from passing through the plasma etch-resistant film to the substrate.
